(19) United States
(12) Patent Application Publication
(10) Pub. No.: US 2026/0075997 A1
(43) Pub. Date: Mar. 12, 2026

(54) LIGHT EMITTING DEVICE AND METHOD FOR MANUFACTURING THE SAME

(71) Applicant: Kabushiki Kaisha Toshiba, Kawasaki-shi (JP)

(72) Inventors: Tetsuya Miyagawa, Yokohama Kanagawa (JP); Rei Hashimoto, Edogawa Tokyo (JP); Shinji Saito, Yokohama Kanagawa (JP); Kei Kaneko, Yokohama Kanagawa (JP); Tsutomu Kakuno, Fujisawa Kanagawa (JP); Masatoshi Hirono, Yokohama Kanagawa (JP)

(21) Appl. No.: 19/326,535

(22) Filed: Sep. 11, 2025

(30) Foreign Application Priority Data
Sep. 12, 2024 (JP) 2024-158559

(51) Int. Cl. H10H 20/855; H10H 20/01; H10H 20/821; H10H 20/824

(52) U.S. Cl. CPC H10H 20/855; H10H 20/013; H10H 20/821; H10H 20/824

(57) ABSTRACT

According to one embodiment, a light emitting device includes first and second electrodes and a first structure. At least a part of the first structure is provided between the first and second electrodes. The first structure includes a light emitting layer along a first plane, an optical member, and a stacked body. The stacked body is provided between the optical member and the second electrode. The optical member includes first regions arranged along the first plane, and a second region including a first partial region between the first regions. A refractive index of the first regions is different from a refractive index of the second region. The stacked body includes first layers and second layers. One of the first layers is between one of the second layers and another one of the second layers. A material of the second layers is different from a material of the first layers.

### CROSS-REFERENCE TO RELATED APPLICATIONS

This application is based upon and claims the benefit of priority from Japanese Patent Application No. 2024-158559, filed on Sep. 12, 2024; the entire contents of which are incorporated herein by reference.

### FIELD

Embodiments described herein relate generally to a light emitting device and a method for manufacturing the same.

### BACKGROUND

For example, improved efficiency is desired in light emitting devices such as lasers.

### BRIEF DESCRIPTION OF THE DRAWINGS

FIG. 1 is a schematic cross-sectional view illustrating a light emitting device according to a first embodiment;

FIG. 2 is a schematic cross-sectional view illustrating a part of the light emitting device according to the first embodiment;

FIG. 3 is a schematic cross-sectional view illustrating a part of a light emitting device according to the first embodiment;

FIGS. 4A to 4C are schematic cross-sectional views illustrating a method for manufacturing a light emitting device according to a second embodiment; and

FIGS. 5A to 5C are schematic cross-sectional views illustrating the method for manufacturing the light emitting device according to the second embodiment.

### DETAILED DESCRIPTION

According to one embodiment, a light emitting device includes a first electrode, a second electrode, and a first structure. At least a part of the first structure is provided between the first electrode and the second electrode. The first structure includes a light emitting layer along a first plane, an optical member, and a stacked body. The light emitting layer is between the first electrode and the second electrode in a first direction crossing the first plane. The optical member is provided between the light emitting layer and the second electrode. The stacked body is provided between the optical member and the second electrode. The optical member includes a plurality of first regions arranged along the first plane, and a second region including a first partial region between the plurality of first regions. A first region refractive index of the plurality of first regions is different from a second region refractive index of the second region. The stacked body includes a plurality of first layers and a plurality of second layers. One of the plurality of first layers is between one of the plurality of second layers and another one of the plurality of second layers. The one of the plurality of second layers is between the one of the plurality of first layers and another one of the plurality of first layers. A second material of the plurality of second layers is different from a first material of the plurality of first layers.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

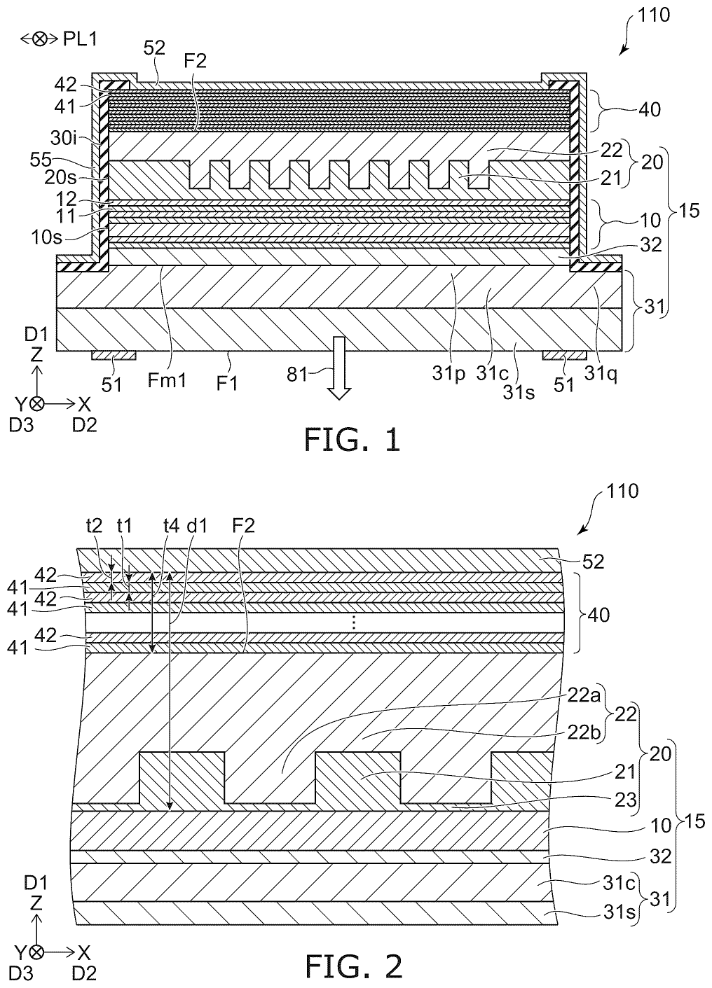

FIG. 1 is a schematic cross-sectional view illustrating a light emitting device according to a first embodiment.

FIG. 2 is a schematic cross-sectional view illustrating a part of the light emitting device according to the first embodiment.

As shown in FIG. 1, a light emitting device 110 according to the embodiment includes a first electrode 51, a second electrode 52, and a first structure 15.

At least a part of the first structure 15 is provided between the first electrode 51 and the second electrode 52. The first structure 15 includes a light emitting layer 10 along a first plane PL1, an optical member 20, and a stacked body 40. The light emitting layer 10 is provided between the first electrode 51 and the second electrode 52 in a first direction D1 crossing the first plane PL1.

The first direction D1 is defined as a Z-axis direction. One direction perpendicular to the Z-axis direction is defined as an X-axis direction. A direction perpendicular to the Z-axis and X-axis directions is defined as a Y-axis direction. The first plane PL1 is, for example, along the X-Y plane.

The optical member 20 is provided between the light emitting layer 10 and the second electrode 52. The stacked body 40 is provided between the optical member 20 and the second electrode 52.

The optical member 20 includes a plurality of first regions 21 and a second region 22. The plurality of first regions 21 are arranged along the first plane PL1. For example, a direction from one of the plurality of first regions 21 to another one of the plurality of first regions 21 may be along a second direction D2 along the first plane PL1. For example, a direction from one of the plurality of first regions 21 to another one of the plurality of first regions 21 may be along a third direction D3 along the first plane PL1. The third direction D3 crosses a plane including the first direction D1 and the second direction D2. The plurality of first regions 21 may be arranged two-dimensionally along the first plane PL1.

As shown in FIG. 2, the second region 22 includes a first partial region 22a. The first partial region 22a is located between the plurality of first regions 21. In the example of FIG. 2, the second region 22 further includes a second partial region 22b. The plurality of first regions 21 are located between the light emitting layer 10 and the second partial region 22b.

The refractive index of the plurality of first regions 21 (first region refractive index) is different from the refractive index of the second region 22 (second region refractive index). By the difference in refractive index, the direction of light changes. In the embodiment, the second region 22 may be a region including at least one selected from the group consisting of a gas, a semiconductor, and a dielectric. The gas may include at least one selected from the group consisting of air and hydrogen, for example. The second region 22 may include a reduced pressure region.

The stacked body 40 includes a plurality of first layers 41 and a plurality of second layers 42. One of the plurality of first layers 41 is between one of the plurality of second layers 42 and another one of the plurality of second layers 42. One of the plurality of second layers 42 is between one of the plurality of first layers 41 and another one of the plurality of first layers 41. For example, the first layer 41 and the second layer 42 may be arranged alternately along the first direction D1. The material (second material) of the plurality of second layers 42 is different from the material (first material) of the plurality of first layers 41.

At least a part of the light emitted from the light emitting layer 10 is spread along the first plane PL1 by the optical member 20. The light passes through the stacked body 40 and is reflected by the second electrode 52. The light reflected by the second electrode 52 passes through the stacked body 40, the optical member 20, and the light emitting layer 10. Light 81 is emitted to the outside (see FIG. 1).

The light 81 travels back and forth through the optical member 20 and the stacked body 40. In a case where the round trip optical path length is not appropriate, the light reflected by the second electrode 52 is attenuated. In a case where the optical path length is appropriate, attenuation is suppressed. For example, the light 81 constructively cooperates with one another. The stacked body 40 has a function of appropriately controlling the optical path length. By the stacked body 40 including the plurality of first layers 41 and the plurality of second layers 42, the thickness of the stacked body 40 can be controlled with high precision in units of the thickness of one of these layers. According to the embodiment, an appropriate optical path length is obtained. According to the embodiment, a light emitting device that can achieve high efficiency can be provided.

As described below, stacked films that become the plurality of first layers 41 and the plurality of second layers 42 may be formed, and a part of the stacked films may be removed to obtain the stacked body 40. The removal may be performed in units of the first layer 41 or the second layer 42. Highly accurate thickness control is performed. By making the material of the second layer 42 (second material) different from the material of the first layer 41 (first material), the first layer 41 or the second layer 42 can be removed with high efficiency. The thickness is controlled with high accuracy.

As shown in FIG. 1, the light emitting device 110 may further include a first semiconductor layer 31. The first semiconductor layer 31 includes a first face F1 and a first intermediate face Fm1. The first face F1 is located between the first electrode 51 and the light emitting layer 10. The first intermediate face Fm1 is located between the first face F1 and the light emitting layer 10. In the example of FIG. 1, the first face F1 is the lower face.

The light 81 emitted from the light emitting layer 10 passes through the optical member 20 and the stacked body 40 and is reflected at the second electrode 52. The light 81 being reflected is configured to pass through the stacked body 40, the optical member 20, and the light emitting layer 10 and to exit from the first face F1. The light 81 passes through the first semiconductor layer 31 and exits from the first face F1.

In this example, the first semiconductor layer 31 includes a substrate 31s and a first semiconductor region 31c. The first semiconductor region 31c is between the substrate 31s and the light emitting layer 10. The first semiconductor region 31c may function as, for example, a first cladding layer.

As already described, the optical member 20 may include the second partial region 22b (see FIG. 2). The second partial region 22b may be in contact with the stacked body 40. At least a part of the second partial region 22b may function as a second cladding layer.

In the embodiment, the first structure 15 is a laser. The light 81 has substantially one peak wavelength. For example, the light 81 has a first peak wavelength and does not have a second peak wavelength. Or, the light 81 has a first peak wavelength and a second peak wavelength, and the intensity at the second peak wavelength is 1/10 or less of the intensity at the first peak wavelength. The light 81 is in phase.

The first structure 15 may be, for example, a quantum cascade laser. The light 81 being highly efficient is obtained. The light emitting layer 10 may be configured to emit light by, for example, an intersubband transition.

The optical member 20 including the plurality of first regions 21 functions as, for example, a photonic crystal. The first structure 15 may be, for example, a face-emitting quantum cascade laser.

As shown in FIG. 1, the first semiconductor layer 31 may include a first portion 31p and a second portion 31q. A direction from the first portion 31p to the second portion 31q crosses the first direction D1. The light emitting layer 10 is located between the first portion 31p and the optical member 20 in the first direction D1. The light emitting layer 10 does not overlap the second portion 31q in the first direction D1. The first structure 15 includes a mesa region. The light emitting layer 10 and the optical member 20 may be included in the mesa region. At least a part of the first portion 31p may be included in the mesa region.

As shown in FIG. 1, the first structure 15 may include a second semiconductor layer 32. The second semiconductor layer 32 is provided between the first semiconductor layer 31 and the light emitting layer 10.

As shown in FIG. 2, the optical member 20 may further include a third region 23. The third region 23 is located between the light emitting layer 10 and the first partial region 22a. The refractive index of the third region 23 is different from the refractive index of the second region 22. The refractive index of the third region 23 may be substantially the same as the refractive index of the plurality of first regions 21. The material of the third region 23 may be substantially the same as the material of the plurality of first regions 21. The plurality of first regions 21 may be continuous with the third region 23.

As shown in FIG. 1, the light emitting layer 10 includes a plurality of first compound layers 11 and a plurality of second compound layers 12. One of the plurality of first compound layers 11 is located between one of the plurality of second compound layers 12 and another one of the plurality of second compound layers 12. One of the plurality of second compound layers 12 is located between one of the plurality of first compound layers 11 and another one of the plurality of first compound layers 11. The first compound layer 11 and the second compound layer 12 may be arranged alternately along the first direction D1.

In one example, the plurality of first compound layers 11 include In_{z1}Ga_{1-z1}As (0<z1<1). The plurality of second compound layers 12 include In_{z2}Al_{1-z2}As (0<z2<1). In one example, the wavelength of the light 81 emitted from the light emitting layer 10 may be not less than 2 μm and not more than 20 μm. The light emitting device 110 may be used, for example, in the analysis or detection of gases, etc. For example, in a case where the detection target is carbon dioxide gas, the wavelength may be, for example, not less than 3 μm and not more than 5 μm. For example, in a case where the detection target is methane gas, the wavelength may be, for example, not less than 2 μm and not more than 4 μm. The wavelength may be set to match the detection target.

In one example, the first regions 21 include Inₓ₁Ga₁₋ₓ₁As (0<x1<1). The second region 22 includes InP. For example, a large difference in refractive index can be obtained The substrate 31s may include, for example, InP. The first semiconductor region 31c may include InP. The second semiconductor layer 32 may include, for example, InGaAs.

In the stacked body 40, the plurality of first layers 41 include, for example, In_{y1}Ga_{1-y1}As (0<y1<1). The plurality of second layers 42 include, for example, InP. A highly homogeneous film is easily obtained. A large difference in etching rate is easily obtained between these layers. The target layer can be removed with high efficiency.

As shown in FIG. 2, the first thickness t1 of one of the plurality of first layers 41 may be, for example, not less than 2 nm and less than 30 nm. The second thickness t2 of one of the plurality of second layers 42 may be, for example, not less than 2 nm and less than 30 nm. By each of these thicknesses being less than 30 nm, it is easy to control the optical path length of the stacked body 40, for example, with an accuracy of 1/10 or less of the wavelength. This allows the optical path length to be controlled with high accuracy compared to the wavelength. Highly efficient light 81 is obtained. These thicknesses are lengths along the first direction D1. The optical path length corresponds to the product of the thickness of the stacked body 40 (stack thickness t4) and the refractive index in the stacked body 40.

One of the plurality of first layers 41 or one of the plurality of second layers 42 may function as an etching stopper. By the thickness of these being 2 nm or more, good in-plane uniformity is easily obtained. For example, the etching stopper function is stably obtained. By each of these thicknesses being less than 30 nm, lattice distortion is easily suppressed. For example, dislocations are suppressed.

As shown in FIG. 2, a distance between the light emitting layer 10 and the second electrode 52 along the first direction D1 is defined as a first distance d1. The average refractive index in the region between the light emitting layer 10 and the second electrode 52 is defined as an average refractive index nₐ. The wavelength of the light emitted from the light emitting layer 10 is defined as a wavelength λ. The first distance d1 may be a substantially odd plurality of λ/(4 nₐ). For example, the average refractive index nₐ, the wavelength λ, and the first distance d1 may satisfy a first condition. In the first condition, the first distance d1 is not less than (2 m-1.1) times and not more than (2 m-0.9) times of λ/(4 nₐ), and “m” is an integer equal to or greater than 1. Such a first distance d1 can effectively suppress, for example, loss due to interference. In one example, the average refractive index nₐ may be, for example, not less than 2.5 and not more than 3.6. In one example, the average refractive index nₐ is, for example, not less than 2.8 and not more than 3.4. The average refractive index nₐ may be, for example, not less than 3.1 and not more than 3.4.

As shown in FIG. 2, the optical member 20 includes a second face F2 facing the stacked body 40. In the example of FIG. 2, the second face F2 contacts the stacked body 40.

As shown in FIG. 1, the light emitting device 110 may further include a reflective member 55. The light emitting layer 10 includes a light emitting layer side-face 10s that crosses the first plane PL1. At least a part of the reflective member 55 faces the light emitting layer side-face 10s. The optical member 20 includes an optical member side-face 20s that crosses the first plane PL1. A part of the reflective member 55 faces the optical member side-face 20s. The reflective member 55 allows the light 81 emitted from the light emitting layer 10 to be extracted to the outside with high efficiency. The reflective member 55 may be continuous with the second electrode 52.

The light emitting device 110 may further include an insulating member 30i. At least a part of the insulating member 30i is provided between the light emitting layer 10 and the reflective member 55. A part of the insulating member 30i is provided between the optical member 20 and the reflective member 55.

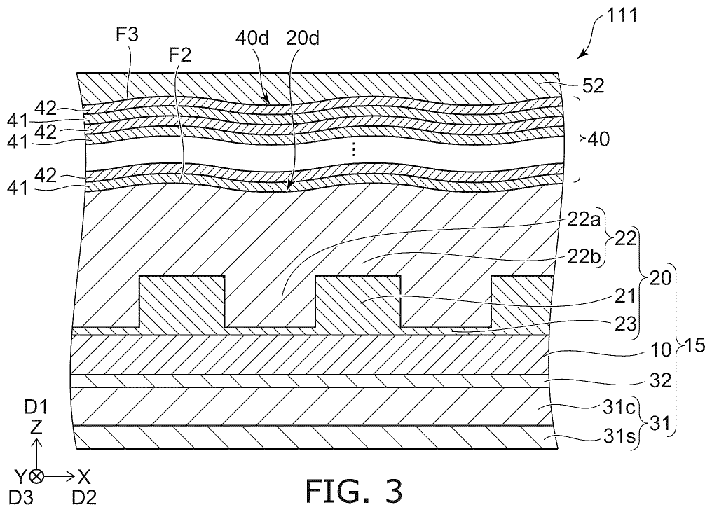

FIG. 3 is a schematic cross-sectional view illustrating a part of a light emitting device according to the first embodiment.

As shown in FIG. 3, in a light emitting device 111 according to the embodiment, the configuration of the optical member 20 is different from the configuration in the light emitting device 110. Except for this, the configuration of the light emitting device 111 may be the same as the configuration of the light emitting device 111.

In the light emitting device 111, the optical member 20 includes the second face F2 facing the stacked body 40. The second face F2 includes a recess 20d. The second face F2 includes projections and recesses. At least a part of the stacked body 40 is located between a part of the optical member 20 and another part of the optical member 20 in the second direction D2 along the first plane PL1. At least a part of the stacked body 40 may be provided in the recess 20d.

For example, the unevenness of the second face F2 may be based on the plurality of first regions 21. The unevenness of the second face F2 may correspond to the plurality of first regions 21. The recess 20d of the second face F2 may correspond to the first partial region 22a of the second region 22. A position of the recess 20d in the second direction D2 may reflect a position of the first partial region 22a in the second direction D2. For example, the recess 20d overlaps the first partial region 22a in the first direction D1. In a case where such a recess 20d exists as well, a part of the stacked body 40 may be filled in the recess 20d. A homogeneous film is obtained.

The stacked body 40 may include a third face F3 facing the second electrode 52. The third face F3 may include a third face recess 40d. The third face recess 40d may overlap the recess 20d of the second face F2 in the first direction D1.

### Second Embodiment

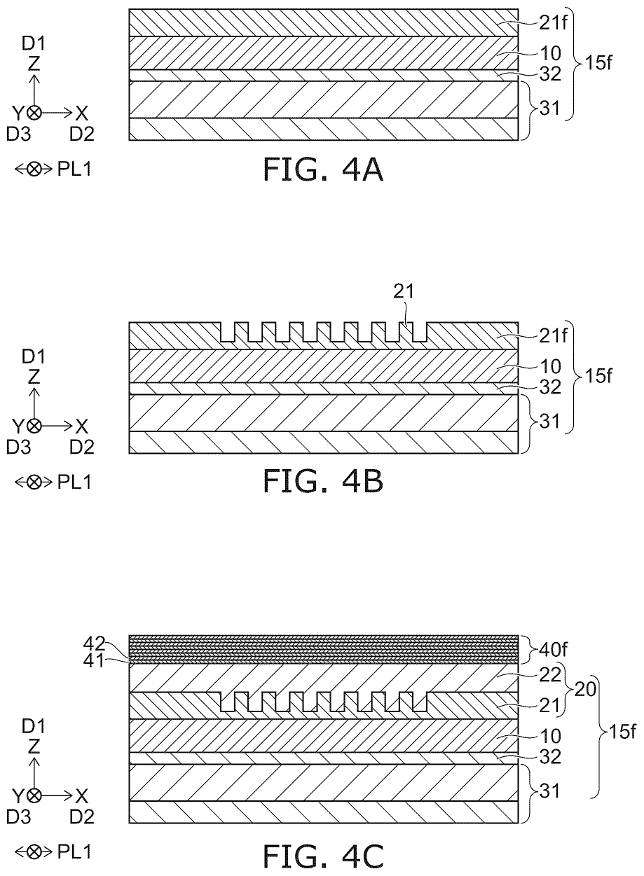

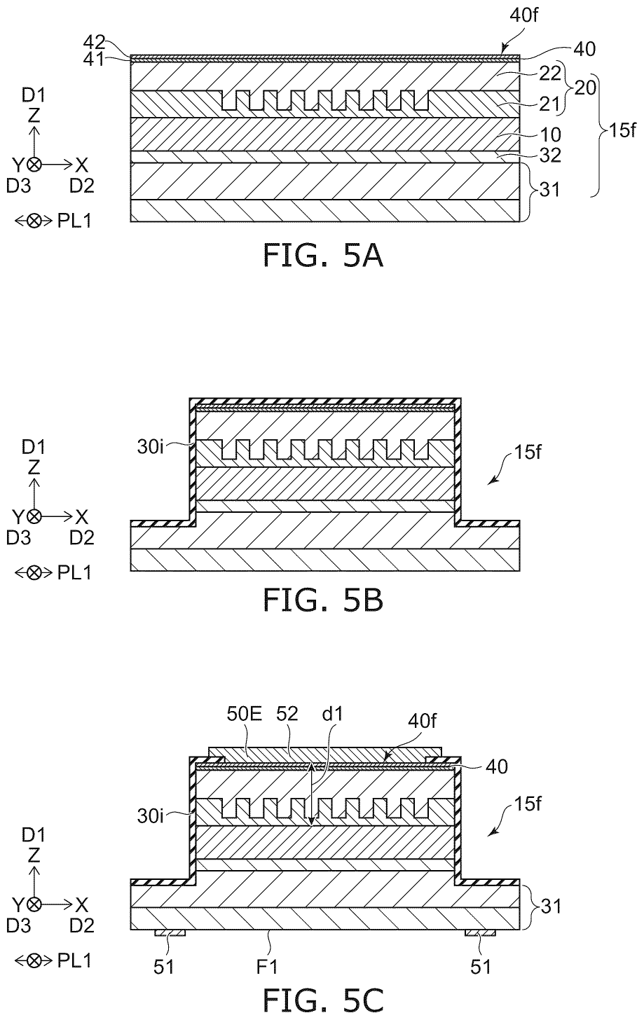

FIGS. 4A to 4C and 5A to 5C are schematic cross-sectional views illustrating a method for manufacturing a light emitting device according to the second embodiment.

As shown in FIG. 4A, a processing body 15f includes the first semiconductor layer 31, the light emitting layer 10, and a first processing layer 21f. The first processing layer 21f forms at least a part of the plurality of first regions 21. The light emitting layer 10 is provided between the first semiconductor layer 31 and the first processing layer 21f. In this example, the second semiconductor layer 32 is provided between the first semiconductor layer 31 and the light emitting layer 10.

As shown in FIG. 4B, a part of the first processing layer 21f is removed. Thereby, the plurality of first regions 21 are formed. For example, dry etching is performed in the processing.

As shown in FIG. 4C, the second region 22 is formed between the plurality of first regions 21. The second region 22 may cover the plurality of first regions 21. Thereby, the optical member 20 is obtained. A stacked processing body 40f is formed on the optical member 20. The stacked processing body 40f includes the plurality of first layers 41 and the plurality of second layers 42.

Thus, the manufacturing method according to the embodiment includes forming a stacked processing body 40f on a processing body 15f. The processing body 15f includes the light emitting layer 10 along the first plane PL1, and the optical member 20 provided on the light emitting layer 10. The stacked processing body 40f includes the plurality of first layers 41 and the plurality of second layers 42. One of the plurality of first layers 41 is located between one of the plurality of second layers 42 and another one of the plurality of second layers 42. One of the plurality of second layers 42 is located between one of the plurality of first layers 41 and another one of the plurality of first layers 41. The first layer 41 and the second layer 42 may be arranged alternately. The second material of the second layer 42 is different from the first material of the first layer 41.

As shown in FIG. 5A, at least a part of the stacked processing body 40f is removed. The removing at least a part of the stacked processing body 40f includes removing at least one of at least one of the plurality of first layers 41 or at least one of the plurality of second layers 42. By removing at least one of these layers, the thickness of the stacked processing body 40f can be controlled with high precision. By removing at least a part of the stacked processing body 40f, the stacked body 40 is obtained.

As shown in FIG. 5B, in this example, a part of the processing body 15f is removed to form a mesa region. The insulating member 30i is formed on the side face and top face of the mesa region.

As shown in FIG. 5C, a part of the insulating member 30i is removed. Thereby, at least a part of the stacked body 40 (stacked processing body 40f) is exposed. An electrode 50E is formed on the stacked processing body 40f (stacked body 40) remaining after the removal. Substantially all of the stacked processing body 40f may be removed. In this case, the optical member 20 is exposed by the removal. The electrode 50E may be formed on the optical member 20 exposed by the removal. The electrode 50E corresponds to, for example, the second electrode 52. The first electrode 51 may be formed on the first face F1 of the first semiconductor layer 31.

Thus, the electrode 50E may be formed on the stacked processing body 40f remaining after the removing at least a part of the stacked processing body 40f, or on the optical member 20 exposed by the removing.

In the embodiment, an etching rate of the plurality of second layers 42 with respect to a first etchant may be higher than an etching rate of the plurality of first layers 41 with respect to the first etchant. For example, the first layer 41 can be removed with high efficiency. An etching rate of the plurality of first layers 41 with respect to a second etchant may be higher than an etching rate of the plurality of second layers 42 with respect to the second etchant. For example, the second layer 42 can be removed with high efficiency. A ratio of the etching rates may be, for example, 10 or more. The ratio may be 50 or more.

In the embodiment, for example, the removing at least a part of the stacked processing body 40f may include satisfying a first condition, which is the average refractive index nₐ between the light emitting layer 10 and the electrode 50E, the first distance d1 (see FIG. 5C) between the light emitting layer 10 and the electrode 50E, and the wavelength λ of the light emitted from the light emitting layer 10. In the first condition, the first distance d1 is not less than (2 m-1.1) times and not more than (2 m-0.9) times of λ/(4 nₐ), and “m” is an integer equal to or greater than 1.

In the embodiment, the first thickness t1 of one of the plurality of first layers 41 may be, for example, not less than 2 nm and not more than 30 nm. The second thickness t2 of one of the plurality of second layers 42 may be, for example, not less than 2 nm and not more than 30 nm.

The embodiments may include the following Technical proposals:

### Technical Proposal 1

A light emitting device, comprising:
a first electrode;
a second electrode; and
a first structure, at least a part of the first structure being provided between the first electrode and the second electrode,
the first structure including:
   a light emitting layer along a first plane;
   an optical member; and
   a stacked body,
the light emitting layer being between the first electrode and the second electrode in a first direction crossing the first plane,
the optical member being provided between the light emitting layer and the second electrode,
the stacked body being provided between the optical member and the second electrode,
the optical member including:
   a plurality of first regions arranged along the first plane, and
   a second region including a first partial region between the plurality of first regions,
a first region refractive index of the plurality of first regions being different from a second region refractive index of the second region,
the stacked body including a plurality of first layers and a plurality of second layers,
one of the plurality of first layers being between one of the plurality of second layers and another one of the plurality of second layers,
the one of the plurality of second layers being between the one of the plurality of first layers and another one of the plurality of first layers, and
a second material of the plurality of second layers being different from a first material of the plurality of first layers.

### Technical Proposal 2

The light emitting device according to Technical proposal 1, wherein
a first thickness of the one of the plurality of first layers is not less than 2 nm and less than 30 nm, and
a second thickness of the one of the plurality of second layers is not less than 2 nm and less than 30 nm.

### Technical Proposal 3

The light emitting device according to Technical proposal 1 or 2, wherein
an average refractive index nₐ between the light emitting layer and the second electrode, a wavelength λ of light emitted from the light emitting layer, and a first distance between the light emitting layer and the second electrode satisfy a first condition,
in the first condition, the first distance is not less than (2 m-1.1) times and not more than (2 m-0.9) times of λ/(4 nₐ), and
the m is an integer equal to or greater than 1.

### Technical Proposal 4

The light emitting device according to any one of Technical proposals 1-3, wherein
the second region further includes a second partial region, and
the plurality of first regions are between the light emitting layer and the second partial region.

### Technical Proposal 5

The light emitting device according to Technical proposal 4, wherein
the second partial region is in contact with the stacked body.

### Technical Proposal 6

The light emitting device according to Technical proposal 1 or 2, further comprising:
a first semiconductor layer including a first face and a first intermediate face,
the first face being between the first electrode and the light emitting layer, and
the first intermediate face being between the first face and the light emitting layer,
wherein
the light emitted from the light emitting layer is configured to pass through the optical member and the stacked body and to be reflected by the second electrode, and
the reflected light passes through the stacked body, the optical member, and the light emitting layer and is emitted from the first face.

### Technical Proposal 7

The light emitting device according to Technical proposal 6, wherein
the first semiconductor layer includes a substrate and a first semiconductor region, and
the first semiconductor region is between the substrate and the light emitting layer.

### Technical Proposal 8

The light emitting device according to Technical proposal 6 or 7, wherein
the first semiconductor layer includes a first portion and a second portion,
a direction from the first portion to the second portion crosses the first direction,
the light emitting layer is between the first portion and the optical member in the first direction, and
the light emitting layer does not overlap the second portion in the first direction.

### Technical Proposal 9

The light emitting device according to any one of Technical proposals 1-8, wherein
the light emitting layer is configured to emit light by intersubband transition.

### Technical Proposal 10

The light emitting device according to any one of Technical proposals 1-9, wherein
the first layers include In_{y1}Ga_{1-y1}As (0<y1<1), and
the second layers include InP.

### Technical Proposal 11

The light emitting device according to any one of Technical proposals 1-10, wherein
the light emitting layer includes a plurality of first compound layers and a plurality of second compound layers,
one of the plurality of first compound layers is between one of the plurality of second compound layers and another one of the plurality of second compound layers,
the one of the plurality of second compound layers is between the one of the plurality of first compound layers and another one of the plurality of first compound layers,
the first compound layers include In_{z1}Ga_{1-z1}As (0<z1<1), and
the second compound layers include In_{z2}Al_{1-z2}As (0<z2<1).

### Technical Proposal 12

The light emitting device according to any one of Technical proposals 1-11, wherein
the first regions include Inₓ₁Ga₁₋ₓ₁As (0<x1<1), and
the second region includes InP.

### Technical Proposal 13

The light emitting device according to any one of Technical proposals 1-12, wherein
the optical member includes a second face facing the stacked body,
the second face includes a recess,
at least a part of the stacked body is between a part of the optical member and another part of the optical member in a second direction along the first plane.

### Technical Proposal 14

The light emitting device according to Technical proposal 13, wherein
the recess overlaps the first partial region in the first direction.

### Technical Proposal 15

The light emitting device according to any one of Technical proposals 1-14, further comprising:
the light emitting layer further includes a reflective member,
the light emitting layer includes a light emitting layer side-face crossing the first plane, and
at least a part of the reflective member faces the light emitting layer side-face.

### Technical Proposal 16

The light emitting device according to any one of Technical proposals 1-15, wherein
the first structure is a surface-emitting quantum cascade laser.

### Technical Proposal 17

A method for manufacturing a light emitting device, the method comprising:
forming a stacked processing body on a processing body including a light emitting layer along a first plane and an optical member provided on the light emitting layer, the stacked processing body including a plurality of first layers and a plurality of second layers, one of the plurality of first layers being between one of the plurality of second layers and another one of the plurality of second layers, the one of the plurality of second layers being between the one of the plurality of first layers and another one of the plurality of first layers, a second material of the plurality of second layers being different from a first material of the plurality of the first layers;
removing at least a part of the stacked processing body; and
forming an electrode on the stacked processing body remaining after the removing, or on the optical member exposed by the removing.

### Technical Proposal 18

The method for manufacturing the light emitting device according to Technical proposal 17, wherein
the removing of the at least the part of the stacked processing body includes to cause an average refractive index nₐ between the light emitting layer and the electrode, a first distance between the light emitting layer and the electrode, and a wavelength λ of light emitted from the light emitting layer to satisfy a first condition,
in the first condition, the first distance is not less than (2 m-1.1) times and not more than (2 m-0.9) times of λ/(4 nₐ), and
the m is an integer equal to or greater than 1.

### Technical Proposal 19

The method for manufacturing the light emitting device according to Technical proposal 17 or 18, wherein
the removing the at least the part of the stacked processing body includes removing at least at least one of the plurality of first layers or at least one of the plurality of second layers.

### Technical Proposal 20

The method for manufacturing the light emitting device according to any one of Technical proposals 17-19, wherein
a first thickness of the one of the plurality of first layers is not less than 2 nm and less than 30 nm, and
a second thickness of the one of the plurality of second layers is not less than 2 nm and less than 30 nm.

According to the embodiment, a light emitting device that can achieve high efficiency and a method for manufacturing the same are provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the light emitting devices such as electrodes, stacked bodies, light emitting bodies, optical members, semiconductor layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all light emitting devices and all methods for manufacturing the same practicable by an appropriate design modification by one skilled in the art based on the light emitting devices and methods for manufacturing the same described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light emitting device, comprising:
a first electrode;
a second electrode; and
a first structure, at least a part of the first structure being provided between the first electrode and the second electrode,
the first structure including:
a light emitting layer along a first plane;
an optical member; and
a stacked body,
the light emitting layer being between the first electrode and the second electrode in a first direction crossing the first plane,
the optical member being provided between the light emitting layer and the second electrode,
the stacked body being provided between the optical member and the second electrode,
the optical member including:
a plurality of first regions arranged along the first plane, and
a second region including a first partial region between the plurality of first regions,
a first region refractive index of the plurality of first regions being different from a second region refractive index of the second region,
the stacked body including a plurality of first layers and a plurality of second layers,
one of the plurality of first layers being between one of the plurality of second layers and another one of the plurality of second layers,
the one of the plurality of second layers being between the one of the plurality of first layers and another one of the plurality of first layers, and
a second material of the plurality of second layers being different from a first material of the plurality of first layers.

2. The light emitting device according to claim 1, wherein
a first thickness of the one of the plurality of first layers is not less than 2 nm and less than 30 nm, and
a second thickness of the one of the plurality of second layers is not less than 2 nm and less than 30 nm.

3. The light emitting device according to claim 1, wherein
an average refractive index nₐ between the light emitting layer and the second electrode, a wavelength λ of light emitted from the light emitting layer, and a first distance between the light emitting layer and the second electrode satisfy a first condition,
in the first condition, the first distance is not less than (2 m-1.1) times and not more than (2 m-0.9) times of λ/(4 nₐ), and
the m is an integer equal to or greater than 1.

4. The light emitting device according to claim 1, wherein
the second region further includes a second partial region, and
the plurality of first regions are between the light emitting layer and the second partial region.

5. The light emitting device according to claim 4, wherein
the second partial region is in contact with the stacked body.

6. The light emitting device according to claim 1, further comprising:
a first semiconductor layer including a first face and a first intermediate face,
the first face being between the first electrode and the light emitting layer, and
the first intermediate face being between the first face and the light emitting layer,
wherein
the light emitted from the light emitting layer is configured to pass through the optical member and the stacked body and to be reflected by the second electrode, and
the reflected light passes through the stacked body, the optical member, and the light emitting layer and is emitted from the first face.

7. The light emitting device according to claim 6, wherein
the first semiconductor layer includes a substrate and a first semiconductor region, and
the first semiconductor region is between the substrate and the light emitting layer.

8. The light emitting device according to claim 6, wherein
the first semiconductor layer includes a first portion and a second portion,
a direction from the first portion to the second portion crosses the first direction,
the light emitting layer is between the first portion and the optical member in the first direction, and
the light emitting layer does not overlap the second portion in the first direction.

9. The light emitting device according to claim 1, wherein
the light emitting layer is configured to emit light by intersubband transition.

10. The light emitting device according to claim 1, wherein
the first layers include In_{y1}Ga_{1-y1}As (0<y1<1), and
the second layers include InP.

11. The light emitting device according to claim 1, wherein
the light emitting layer includes a plurality of first compound layers and a plurality of second compound layers,
one of the plurality of first compound layers is between one of the plurality of second compound layers and another one of the plurality of second compound layers,
the one of the plurality of second compound layers is between the one of the plurality of first compound layers and another one of the plurality of first compound layers,
the first compound layers include In_{z1}Ga_{1-z1}As (0<z1<1), and
the second compound layers include In_{z2}Al_{1-z2}As (0<z2<1).

12. The light emitting device according to claim 1, wherein
the first regions include Inₓ₁Ga₁₋ₓ₁As (0<x1<1), and
the second region includes InP.

13. The light emitting device according to claim 1, wherein
the optical member includes a second face facing the stacked body,
the second face includes a recess,
at least a part of the stacked body is between a part of the optical member and another part of the optical member in a second direction along the first plane.

14. The light emitting device according to claim 13, wherein
the recess overlaps the first partial region in the first direction.

15. The light emitting device according to claim 1, further comprising:
the light emitting layer further includes a reflective member,
the light emitting layer includes a light emitting layer side-face crossing the first plane, and
at least a part of the reflective member faces the light emitting layer side-face.

16. The light emitting device according to claim 1, wherein
the first structure is a surface-emitting quantum cascade laser.

17. A method for manufacturing a light emitting device, the method comprising:
forming a stacked processing body on a processing body including a light emitting layer along a first plane and an optical member provided on the light emitting layer, the stacked processing body including a plurality of first layers and a plurality of second layers, one of the plurality of first layers being between one of the plurality of second layers and another one of the plurality of second layers, the one of the plurality of second layers being between the one of the plurality of first layers and another one of the plurality of first layers, a second material of the plurality of second layers being different from a first material of the plurality of the first layers;
removing at least a part of the stacked processing body; and
forming an electrode on the stacked processing body remaining after the removing, or on the optical member exposed by the removing.

18. The method for manufacturing the light emitting device according to claim 17, wherein
the removing of the at least the part of the stacked processing body includes to cause an average refractive index nₐ between the light emitting layer and the electrode, a first distance between the light emitting layer and the electrode, and a wavelength λ of light emitted from the light emitting layer to satisfy a first condition,
in the first condition, the first distance is not less than (2 m-1.1) times and not more than (2 m-0.9) times of λ/(4 nₐ), and
the m is an integer equal to or greater than 1.

19. The method for manufacturing the light emitting device according to claim 17, wherein
the removing the at least the part of the stacked processing body includes removing at least at least one of the plurality of first layers or at least one of the plurality of second layers.

20. The method for manufacturing the light emitting device according to claim 17, wherein
a first thickness of the one of the plurality of first layers is not less than 2 nm and less than 30 nm, and
a second thickness of the one of the plurality of second layers is not less than 2 nm and less than 30 nm.
